(19) United States
(12) Patent Application Publication
(10) Pub. No.: US 2010/0117764 A1
(43) Pub. Date: May 13, 2010

(54) Assisted selective growth of highly dense and vertically aligned carbon nanotubes

(75) Inventors: Yunyu Wang, Austin, TX (US); Paul S. Ho, Austin, TX (US); Li Shi, Austin, TX (US); Zhen Yao, Austin, TX (US)

Correspondence Address: Schwabe Williamson & Wyatt;PACWEST CENTER, SUITE 1900, 1211 SW FIFTH AVENUE, PORTLAND, OR, 97204, US

(73) Assignee: Board of Regents, The University of Texas System

(21) Appl. No.: 11/405,657

(22) Filed: Apr. 17, 2006

(51) Int. Cl. H01P 1/20; C23C 16/26; C03C 17/38

(52) U.S. Cl. 333/204; 427/249.4; 428/634; 977/843

(57) ABSTRACT

The selective growth of vertically aligned, highly dense carbon nanotube (CNT) arrays using a thermal catalytic chemical vapor deposition (CCVD) method via selection of the supporting layer where the thin catalyst layer is deposited on. A thin iron (Fe) catalyst deposited on a supporting layer of tantalum (Ta) yielded CCVD growth of the vertical dense CNT arrays. Cross-sectional transmission electron microscopy revealed a Vollmer-Weber mode of Fe island growth on Ta, with a small contact angle of the islands controlled by the relative surface energies of the supporting layer, the catalyst and their interface. The as-formed Fe island morphology promoted surface diffusion of carbon atoms seeding the growth of the CNTs from the catalyst surface.

### TECHNICAL FIELD

The present invention relates in general to the growth of carbon nanotubes in a selective manner.

### BACKGROUND INFORMATION

Carbon nanotubes (CNTs) have been proposed as building blocks for the future generation of computer chips due to their high thermal conductivity, large current-carrying capacity, and excellent physical and chemical stabilities. However, to integrate with conventional chips based on silicon technology, highly dense and ordered aligned CNTs are needed. Although CNTs have been produced by many different methods, most of such efforts to control CNT growth have been achieved by adjusting the precursor gases and their flow rates, synthesis pressure and temperature, external bias, and catalyst compositions and sizes. The quality of the CNTs in terms of yield, film coverage, density, alignment, uniformity and pattern formation have not been sufficient to meet the requirements of microelectronics applications. So far, the integration of CNT structures with devices on silicon chips has been very limited, and significant improvements are required.

Careful selection of catalysts and supporting materials are known to be critical in controlled growth of CNTs. Several groups have studied CNT growth on different catalysts and supporting metal layers. A supporting layer may be added below the catalyst layer to prevent the catalyst from reacting with or diffusing into the substrate, or to improve the adhesion between the catalyst layer and the substrate. However, in these studies, catalyst films thicker than 10 nm were used and only low-density CNTs with diameters larger than 50 nm or carbon fibers with diameters larger than 100 nm and with stacking cups or bamboo structures were obtained. In most cases, rough catalyst surfaces or large catalyst islands, formed prior to the growth, were provided as nucleation sites for the formation of large carbon nanotubes or fibers; the surface morphology of the supporting layer did not affect much of the CNT growth morphology. For growth of highly dense CNTs with small diameters, small catalyst particles or thin catalyst films need to be used, where the surface morphology and microstructures of the catalyst layer become important and have to be controlled. In a recent study, CNTs were grown on thin cobalt/titanium/tantalum/copper multi-layers for an ULSI interconnect application where a tantalum (Ta) layer was used as a barrier to prevent copper from diffusing into the substrate, and the cobalt/titanium bilayer was used to catalyze the growth of CNTs. The CNTs were found to be curly and not well aligned. This indicates that the use of a Ta layer without an appropriate match with the catalyst layer is not sufficient to achieve the growth of dense and aligned CNTs.

### SUMMARY OF THE INVENTION

The present invention addresses the foregoing needs by selective growth of dense CNT structures using a catalytic template layer. A template formed by depositing a thin iron (Fe) catalytic layer on a thin layer of tantalum (Ta) significantly enhances the growth of vertically aligned CNT arrays with densities exceeding 10¹¹ per cm².

One advantage of the present invention is that it improves CNT yield, film coverage and uniformity. Another advantage of the present invention is that it produces patterned highly dense CNT films with a vertical alignment.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-sectional SEM image of vertically aligned highly dense CNTs grown on a Ta barrier layer on copper interconnect lines on a wafer;

FIG. 2 shows SEM images of CNTs grown on various supporting materials;

FIG. 3 shows SEM images of surface morphologies of annealed Fe layers on various supporting layers of Ta, SiO₂, Cr and Pd, where inset images to (c) and (d) are SEM images of the surface of the Cr and Pd supporting layers after annealing without Fe deposition (scale bars are 200 nm for (a)-(d), and 1 μm for all insets, respectively);

FIG. 4 shows cross-sectional TEM images of Fe islands formed on Ta and SiO₂ supporting layers, where inset image (a) shows 9 nm thick Fe on Ta, inset image (b) shows 9 nm thick Fe on SiO₂, inset image (c) shows a high resolution TEM image of a CNT grown on 3 nm Fe on Ta, and inset image (d) shows a schematic of a catalyst island formation under balance of the surface energies;

FIG. 5 shows SEM images of patterned vertically aligned CNTs with high densities where inset image (a) show 5, 10 and 20 μm wide highly dense vertical CNT columns grown on pre-defined patterns of 3 nm thick Fe on a Ta support, and inset image (b) show 4 μm wide highly dense vertical CNT films grown in via holes, on the bottom of which 9 nm thick Fe was deposited on Ta;

FIGS. 6A-6E illustrate process steps in accordance with embodiments of the present invention; and

FIG. 7 illustrates an embodiment of an RF filter configured in accordance with the present invention.

### DETAILED DESCRIPTION

In the following description, numerous specific details are set forth such as specific device configurations, etc. to provide a thorough understanding of the present invention. However, it will be obvious to those skilled in the art that the present invention may be practiced without such specific details.

Refer now to the drawings wherein depicted elements are not necessarily shown to scale and wherein like or similar elements are designated by the same reference numeral through the several views.

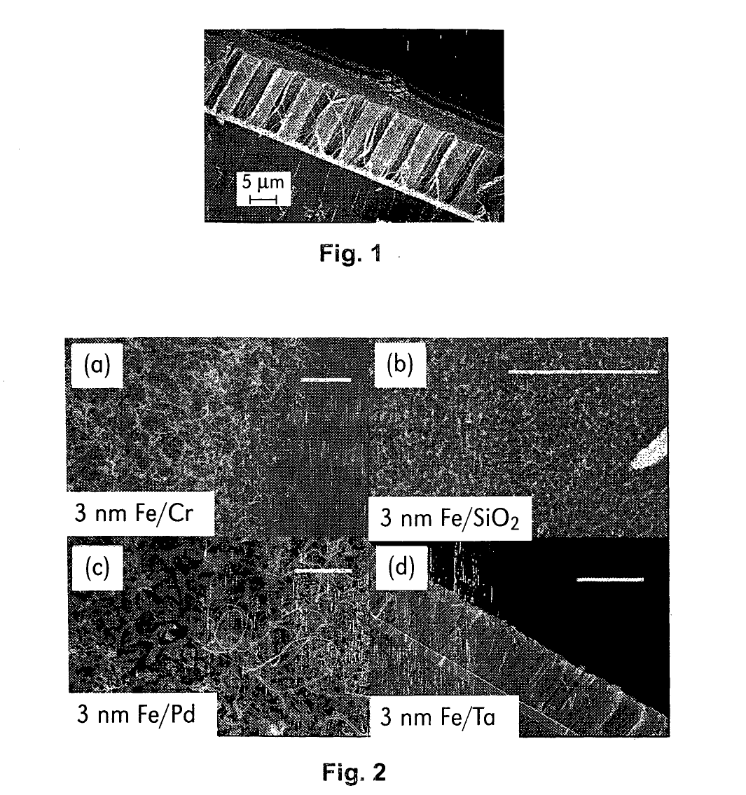

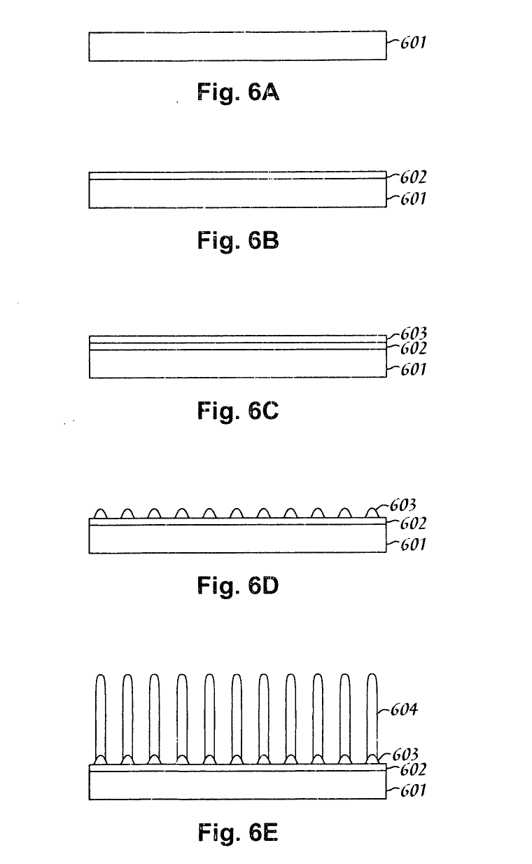

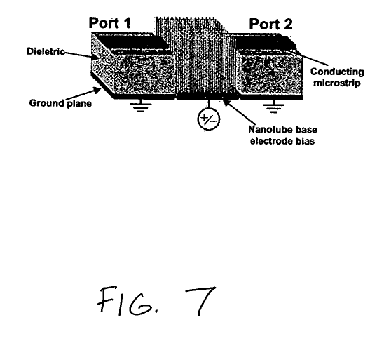

Referring to FIGS. 6A-6E, in embodiments of the present invention as described hereafter, carbon nanotubes may be grown using thermal catalytic chemical vapor deposition (CCVD) on a thick SiO₂ film (e.g., 300 nm) thermally grown on a Si wafer (601 in FIG. 6A). Substrate materials are not limited to SiO₂. Other commonly used substrates may be used, such as silicon, aluminum oxide, quartz, glass, and various metal materials. As further described hereafter, a Fe/Ta bilayer provides a template for selective growth of vertically aligned, dense CNT films. Referring to FIG. 6B, a film of Ta 602 is deposited on substrate 601. Such a film may be ˜5-25 nm thick. However, the present invention is not limited to Ta. Other high surface energy materials, such as (but not limited to) tantalum nitride and tungsten may also be used. An iron (Fe) thick film 603 with a thickness of 3-9 nm is deposited by electron beam evaporation and used as a catalyst (FIG. 6C). The catalyst materials are not limited to iron. Other transition metals commonly used for CNTs may be used, e.g., nickel and cobalt. Annealing of Fe film 603 produces Fe islands 603 as illustrated in FIG. 6D. The carbon nanotube 604 growth may be conducted in a quartz tube furnace (not shown). During the growth, the furnace may be ramped up from room temperature (RT) to 700° C. in hydrogen (H₂) with a flow rate of 11/min, and stabilized at 700° C. for 1 minute; then the growth is initiated by introducing acetylene (C₂H₂) into a furnace with a flow rate of 100 ml/min. The growth is conducted at atmospheric pressure and the growth time varied from 1 to 6 min. FIG. 1 shows a cross-section scanning electron microscopy (SEM) image of vertically aligned, highly dense CNTs grown on pre-patterned wafers in accordance with the present invention, with a CNT density of approximately 10¹¹/cm².

To demonstrate advantages of the present invention, a series of experiments were conducted to investigate the effect of the supporting material on CNT growth by thermal CCVD. First, an Fe (iron) catalyst with the same thicknesses of about 3 nm (nanometers) was deposited on different substrates, including a 300-nm-thick SiO₂ (silicon dioxide) film as well as a 20-nm-thick Ta (tantalum), Pd (palladium), and Cr (chromium) layers on a 300-nm-thick SiO2 (silicon dioxide) film. The Fe on Cr and Fe on SiO₂ produced random CNTs with low-density film coverage, where Fe on Pd resulted in the lowest growth yield, as shown in FIGS. 2 (a)-(c). However, in the case of Fe on Ta, the growth was greatly enhanced yielding CNTs with high density and uniformity, as shown in FIG. 2(d). Moreover, vertically aligned dense CNTs were always obtained within a range of Fe film thicknesses from 3 to 9 nm on the Ta support. In the thickness range of 3 to 9 nm, the CNT diameters were found to increase with increasing Fe thickness. On the contrary, random growth with poor coverage was always observed on the SiO_{2.} Cr and Pd substrates. Additionally, different supporting layer thicknesses were investigated, including a 25 nm and a 50 nm thick Ta layer, with no apparent different effects on the CNT growth.

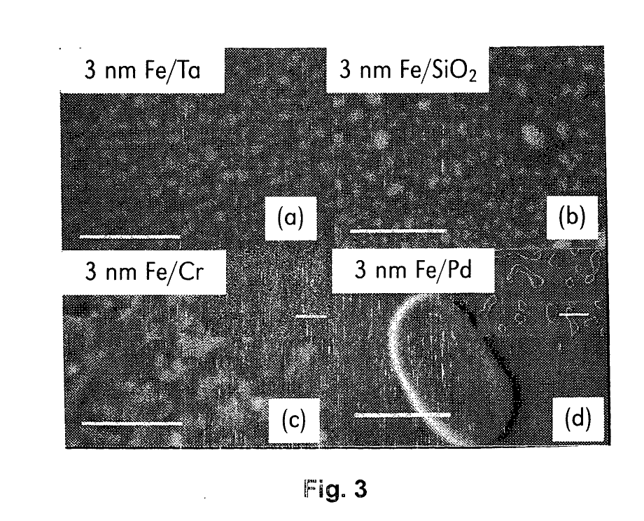

To investigate how the supporting materials affect the formation of the catalyst islands, SEM was used to examine the Fe thin films deposited on different supporting materials after the Fe films were annealed at 700° C. for 1 minute. The surface morphologies observed by SEM are shown in FIGS. 3(a)-(d). For a 3 nm thick Fe layer deposited on Ta, the Fe islands formed after annealing show a narrow range of size distribution from about 15 to 30 nm, and the Fe islands are densely packed reaching a density of about 10¹¹/cm² as shown in FIG. 3(a). Similarly, the Fe islands formed on SiO₂ after annealing were 15-30 nm in size (FIG. 3b) FIGS. 3(c) and (d) show the morphologies of 3 nm thick Fe layers deposited on the Cr layer and the Pd layer after annealing, respectively. The Fe layer on the Cr supporting layer was a continuous film with a very rough surface, and the annealed Fe layer on the Pd support exhibited isolated islands larger than 200 nm.

A 9 nm thick Fe layer was deposited on supporting layers of Ta, Cr, Pd and SiO₂, respectively, and annealed under the same condition. It was found that the Fe island size, distribution, and density on Ta and SiO₂ were greatly influenced by the Fe film thickness, i.e., for 9 nm thick Fe on Ta, the islands were isolated with sizes ranging from about 20 to 90 nm. Similarly, annealed Fe islands on SiO₂ also showed increasing island sizes and a large size distribution. For the Cr or Pd supporting layer, the surface morphologies of the annealed Fe layer are similar to those shown in FIGS. 3 (c)-(d), and there is no obvious dependence on the Fe film thickness.

Moreover, the different supporting layers were annealed without the Fe catalyst layer under the same conditions. The Ta support exhibits a smooth surface without pin holes after annealing, while both the Cr and Pd films became discontinuous with pin holes and large islands as shown in the insets of FIGS. 3(c) and 3(d). Thus, the Ta support layer shows a much better thermal stability in addition to better adhesion with the SiO₂ substrate than the Cr and Pd supporting layers. As the temperature is ramped up to 700° C. during the growth, the surface morphology of the Ta support layer remains smooth, thus providing a smooth and uniform template for the formation of uniform and fine Fe islands. In contrast, pinholes and large islands were found in both the Cr and Pd support layers after annealing, preventing the formation of uniform Fe islands.

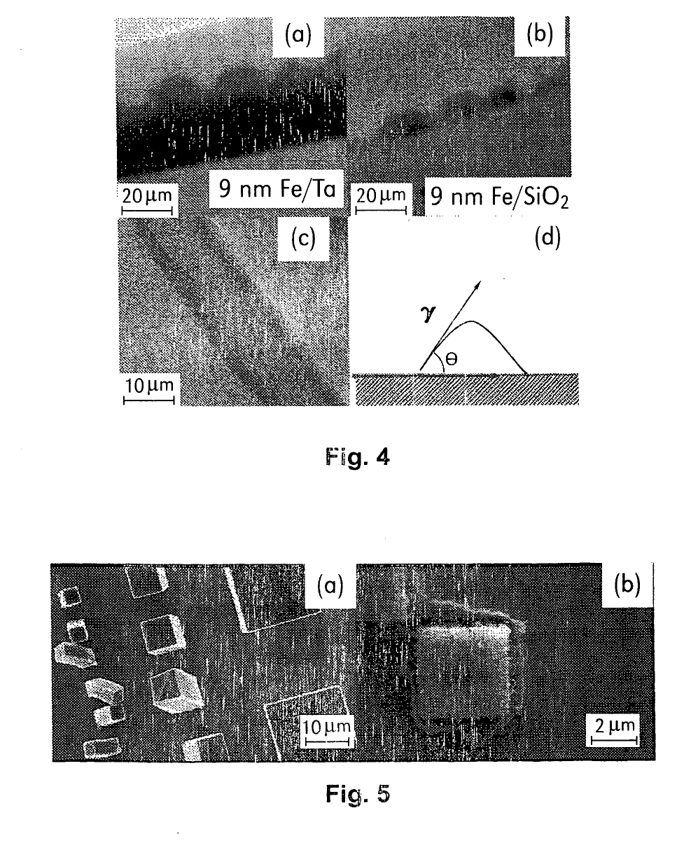

Cross-sectional TEM was used to investigate the morphologies of the annealed Fe islands on the Ta and SiO₂ substrates in order to gain a better understanding of the effect of the supporting material on the formation and morphology of the Fe islands. FIGS. 4(a)-(b) are TEM images of Fe islands formed after 9 nm thick Fe layers were deposited respectively on Ta and SiO₂ and annealed. The Fe islands on both supporting materials showed typical Vollmer-Weber mode of growth. The island shape, however, was distinctly different; on the Ta substrate, it had a hemispherical shape with small contact angles but on the SiO₂ substrate, a bead shape with much larger contact angles. High resolution TEM revealed that typical CNTs grown on a 3 nm thick Fe/Ta bilayer were hollow multi-wall carbon nanotubes with 5 walls and a diameter of about 10 nm, as shown in FIG. 4(c).

The morphology and contact angle of the Fe islands can be accounted for by considering the balance of the surface energies for the catalyst island as shown in FIG. 4(d)

cos θ=(γₛᵥ−γ_{fs})/γ_{fv}

where θ is the contact angle, and f, s, and v represent film, substrate and vacuum, respectively, and a pair of the subscripts refers to the interface between the indicated phases. For the case of the Fe island on Ta, 0<cos θ<1, implying that the surface energy of the Ta substrate exceeds that of the Fe/Ta interface. In contrast, for the Fe island on SiO₂, 0>cos θ>−1, implying that the surface energy of SiO₂ is less than that of the Fe/SiO₂ interface. The observed morphologies of the Fe islands are consistent with the relative magnitudes of the reported surface energies, i.e. ˜2100-2200 ergs/cm² for Ta, 43-106 ergs/cm² for SiO₂, and 1880-2150 ergs/cm² for Fe. These surface and interface energies control the island size formed on the substrate depending on the amount of Fe overlayer deposited.

During the CCVD process of the present invention, carbon (C) atoms are firstly driven by chemical potential gradient to the Fe island surface, then form sp2 carbon fragments. Subsequently, after the nucleation, more C atoms are incorporated into carbon fragment edges and sustain the growth. Both bulk (D_{b}) and surface diffusion (Dₛ) can transport C atoms to the growth edge. However, as catalyst particles are reduced to the smaller sizes, surface diffusion becomes the major mass transport mechanism due to large surface area volume ratios. (See, Wang, Y. Y., Gupta, S., Nemanich, R. J., Liu, Z. J. and Lu, C. Q., Hollow To Bamboolike Internal Structure Transition Observed In Carbon Nanotube Films, J. Appl. Phys 98, 014312 (2005); Helveng S., López-Cartes C., Sehested J., Hansen P. L., Clausen B. S., Rostrup-Nielsen J. R., Abild-Pedersen F. and Nrskov J. K., Atomic-Scale Imaging Of Carbon Nanofibre Growth, Nature 427, 426-429 (2004); and Raty, J., Gygi, F. and Calli, G., Growth of Carbon Nanotubes on Metal Nanoparticles: A Microscopic Mechanism From Ab Initio Molecular Dynamics Simulations, Phys. Rev. Lett. 95, 096103 (2005)). Although surface diffusion is a fast process due to a lower activation energy compared to the bulk diffusion, it is greatly influenced by the shapes and curvatures of the surface structures, therefore resulting in distinctly different growth scenarios, i.e., uniform vs. random growth. Here surface diffusion is facilitated by an acute θ of less than 90° as for the case of Fe on Ta, but not for an oblique θ exceeding 90° as for the case of Fe on SiO₂. This difference seems to have a significant effect in the aligned growth of the CNTs. Combined with the formation of uniform Fe islands with a narrow size distribution on the Ta support, the fast surface diffusion due to the acute θ and the high catalyst activity associated with small particle sizes may have facilitated the growth of dense CNTs that support each other to grow in the vertical direction.

To demonstrate that the Ta support allows for the growth of vertically aligned and dense CNTs on a pre-defined pattern, electron beam lithography (EBL) and a lift-off process was used to form 5, 10, and 20 μm wide square patterns of 9 nm thick Fe on 20 nm thick Ta support, along with the thermal CCVD method previously described to grow highly dense CNT columns on the patterns, as shown in FIG. 5(a).

The method may also be employed with a Ta support to grow CNT films in patterned via holes. In the fabrication process, a 20 nm thick Ta layer is sputtered on a substrate, and a 500 nm thick SiO₂ film deposited on the Ta layer. About 260 nm thick polymethyl-methacrylate (PMMA) is spun on the SiO₂ film and patterned using EBL. Via holes are etched into the SiO₂ film with the PMMA pattern as an etching mask. Subsequently, a 9 nm thick Fe layer is deposited on the wafer. Only the Fe and Ta films deposited on the bottom of the via holes are left after the PMMA layer is stripped in acetone. As shown in FIG. 5(b), highly dense CNTs may be grown from the Fe catalyst patterned at the bottom of the 4 μm wide via hole with the use of the thermal CCVD method.

This CNT growth method employing a Ta support can be readily used to grow

CNT via structures on ULSI copper interconnect structures since Ta is used as the barrier layer on copper interconnects. This method, which is simple without the need of complicated equipment such as a microwave plasma CVD tool, can also be used for selective growth of highly dense, vertically aligned, and high-quality CNTs directly on a metal electrode for other applications.

FIG. 7 illustrates a schematic of a waveguide-embedded nanotube array RF filter configured in accordance with embodiments of the present invention. Other devices, such as supporting structures, vias in microchips and field emitters in a flat panel display, may be constructed with dense groupings of aligned CNTs grown in accordance with the present invention.

Although the present invention and its advantages have been described in detail, it should be understood that various changes, substitutions and alterations can be made herein without departing from the spirit and scope of the invention as defined by the appended claims.

1. A method for growing carbon nanotubes on a substrate, comprising the steps of:
depositing a layer of tantalum on the substrate;
depositing an iron catalyst layer on the layer of tantalum;
and growing carbon nanotubes from the iron catalyst layer.

2. The method as recited in claim 1, wherein the step of depositing the iron catalyst layer on the layer of tantalum further comprises the step of annealing the iron catalyst layer to form islands of iron from which the carbon nanotubes are grown.

3. The method as recited in claim 1, wherein the substrate comprises silicon dioxide on silicon.

4. The method as recited in claim 1, wherein the growing step comprises a chemical vapor deposition method.

5. The method as recited in claim 4, wherein the chemical vapor deposition method comprises a thermal catalytic chemical vapor deposition method.

6. A structure comprising:
a substrate;
a layer of tantalum on the substrate;
an iron catalyst layer on the layer of tantalum, wherein a surface energy of the tantalum layer exceeds a surface energy of an interface between the tantalum layer and the iron catalyst layer; and
carbon nanotubes grown from the iron catalyst layer.

7. The structure as recited in claim 6, wherein the iron catalyst layer is annealed to form islands of iron from which the carbon nanotubes are grown.

8. The structure as recited in claim 6, wherein the substrate comprises silicon dioxide on silicon.

9. A structure comprising:
a first metal layer deposited on a substrate;
a catalyst layer deposited on the first layer, wherein a surface energy of the first metal layer exceeds a surface energy of an interface between the first metal layer and the catalyst layer resulting in islands of the catalyst layer forming on the first metal layer; and
nanotubes grown from the islands of the catalyst layer.

10. The structure as recited in claim 9, wherein the catalyst layer comprises iron.

11. The structure as recited in claim 9, wherein the first metal layer comprises tantalum.

12. The structure as recited in claim 10, wherein the first metal layer comprises tantalum.

13. The structure as recited in claim 9, wherein the substrate comprises silicon.

14. The structure as recited in claim 9, wherein the substrate comprises silicon dioxide on silicon.

15. The structure as recited in claim 12, wherein the structure comprises a via.

16. The structure as recited in claim 12, wherein the structure comprises an RF filter.

17. The structure as recited in claim 16, wherein the RF filter further comprises:
a first conductor on a first dielectric;
a second conductor on a second dielectric; and
the carbon nanotubes sandwiched between the dielectrics.

18. A method for growing nanotubes on a substrate, comprising the steps of:
depositing a first layer on a substrate;
depositing a catalyst layer on the first layer, wherein a surface energy of the first layer exceeds a surface energy of an interface between the first layer and the catalyst layer resulting in islands of the catalyst layer forming on the first layer; and
growing nanotubes on the catalyst layer.

19. The method as recited in claim 18, wherein the catalyst layer comprising iron.

20. The method as recited in claim 18, wherein the first layer comprises tantalum.

21. The structure as recited in claim 9, wherein the islands are hemispherical.

22. The structure as recited in claim 21, wherein the hemispherical islands form an acute contact angle with the first metal layer of less than 90°.
